(19) United States
(12) Patent Application Publication
(10) Pub. No.: US 2011/0176271 A1
(43) Pub. Date: Jul. 21, 2011

(54) COMPUTER SYSTEM WITH COOLING AIRFLOW PASSAGES

(75) Inventors: GUANG-YI ZHANG, Shenzhen City (CN); JIA-QI FU, Shenzhen City (CN)

(73) Assignees: HONG FU JIN PRECISION INDUSTRY (ShenZhen) CO., LTD, Shenzhen City (CN); HON HAI PRECISION INDUSTRY CO., LTD., Tu-Cheng (TW)

(21) Appl. No.: 12/818,110

(22) Filed: Jun. 17, 2010

(30) Foreign Application Priority Data
Jan. 16, 2010 (CN) 201010300372.8

(51) Int. Cl. H05K 7/14

(52) U.S. Cl. 361/679.33; 361/679.49

(57) ABSTRACT

An exemplary computer system includes a casing, and plural brackets, hard disk drives, cooling fans and system fans received in the casing. The casing defines plural through holes and ventilating holes at two opposite sides thereof, respectively. The brackets are evenly distributed in the casing side by side along a direction perpendicular to each of the two opposite sides of the casing. Each bracket includes two parallel boards each defining plural apertures. The hard disk drives each are sandwiched between the two parallel boards of one bracket. The hard disk drives and the apertures are alternating. The cooling fans are disposed between the brackets. The system fans are received in the casing, and located between the brackets and the ventilating holes. The cooling fans and systems are aligned in series.

### BACKGROUND

1. Technical Field

The disclosure generally relates to computer systems, and more particularly, to a computer system having a plurality of cooling airflow passages for enhancing a heat dissipation efficiency thereof.

2. Description of Related Art

Generally, a plurality of electronic components, such as hard disk drives, is installed in a computer system such as a server system. For minimal size and volume, the electronic components in the computer system are densely arranged. However, heat generated during operation of the electronic components is not easily dissipated as a result.

What is needed, therefore, is a computer system which can overcome the limitations described.

### BRIEF DESCRIPTION OF THE DRAWINGS

FIG. 1 is an isometric, assembled view of a computer system in accordance with an exemplary embodiment of the disclosure.

FIG. 2 is similar to FIG. 1, but shows a front segment of a cover and an end plate of the computer system both detached from the computer system.

FIG. 3 is similar to FIG. 1, but shows a drawer of the computer system partly drawn out from the computer system, and a hard disk drive of the computer system taken out from the drawer.

FIG. 4 is an enlarged view of part of FIG. 3.

FIG. 5 is a schematic top view showing airflow in the computer system of FIG. 1.

### DETAILED DESCRIPTION

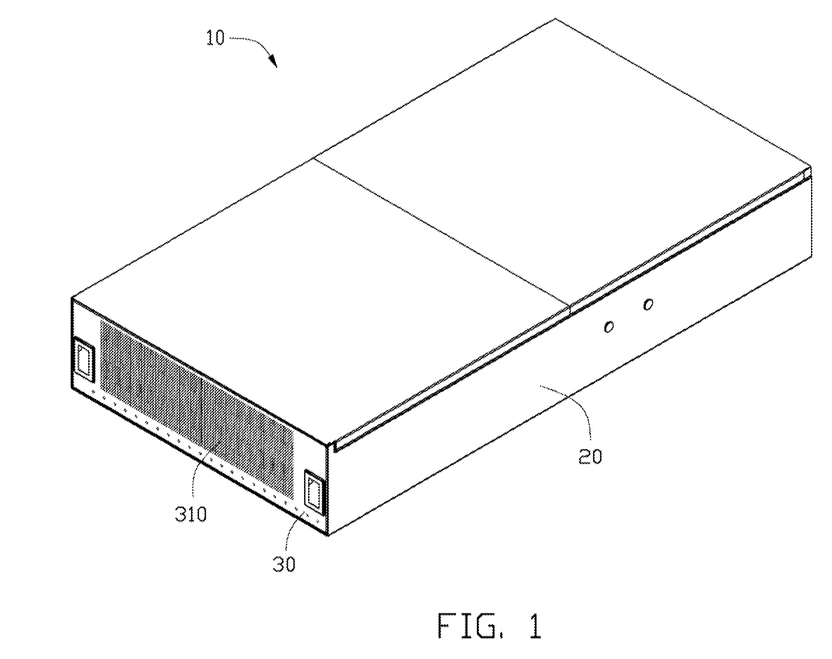

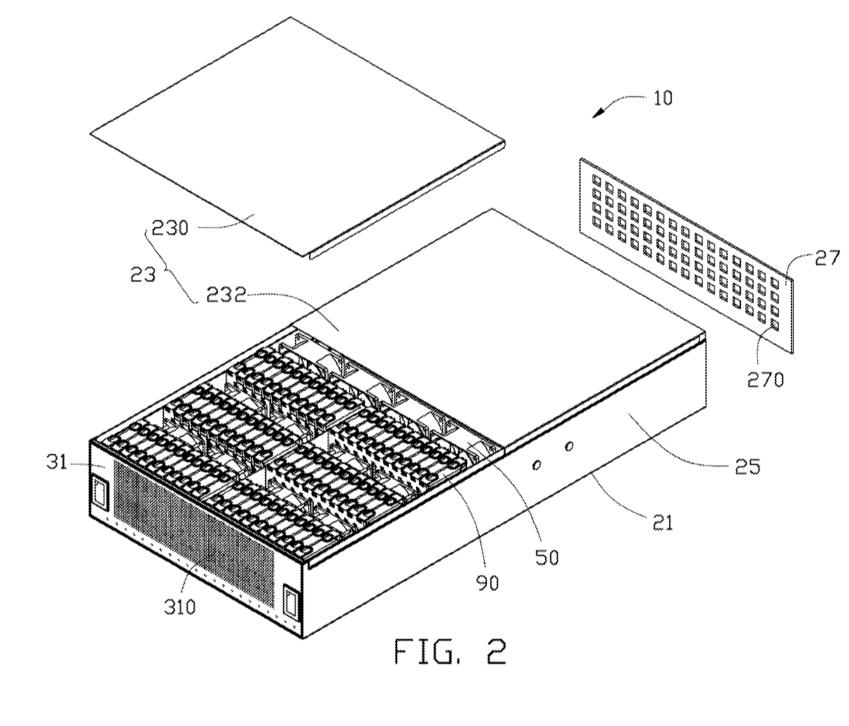

Referring to FIGS. 1, 2 and 3, a computer system 10 according to an exemplary embodiment of the disclosure includes a casing 20, a drawer 30 slidably received in the casing 20, and a plurality of hard disk drives (HDDs) 90 accommodated in the drawer 30.

The casing 20 is hollow and cuboid, preferably made of sheet metal, and includes a bottom plate 21, a top plate 23, two side plates 25 and an end plate 27. The bottom plate 21 and the top plate 23 are the same size and shape, and parallel to each other. The bottom plate 21 is elongated and rectangular. The side plates 25 extend up from opposite sides (left and right sides in FIG. 1) of the bottom plate 21, respectively, to respectively connect opposite sides of the top plate 23. The end plate 27 is coupled to rear ends of the side plates 25, the top plate 23 and the bottom plate 21 to seal the rear end of the casing 20. A plurality of ventilating holes 270 is defined in the end plate 27 to communicate an interior of the casing 20 with the exterior. A rectangular opening (not labeled) is defined at the front end of the casing 20, between front ends of the top plate 23, the bottom plate 21 and the side plates 25. The drawer 30 slides into and out from the casing 20 via the opening.

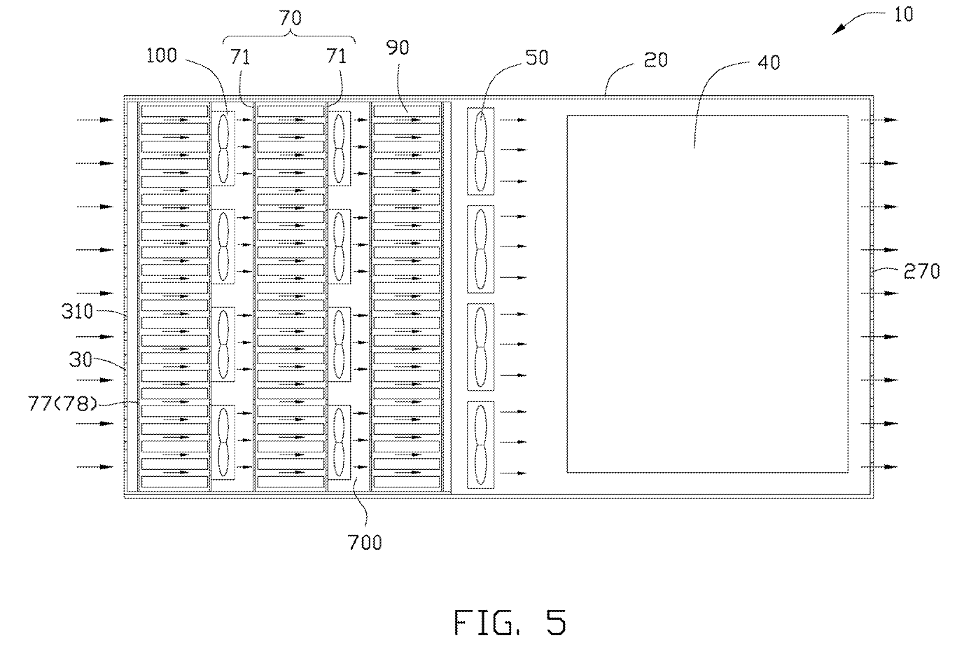

In this embodiment, the top plate 23 includes two segments, i.e., a front segment 230 and a rear segment 232, each detachable from the casing 20. Referring also to FIG. 5, a front area of the interior of the casing 20 corresponding to the front segment 230 of the top plate 23 receives the drawer 30 and a plurality of system fans 50 therein. A rear area of the interior of the casing 20 corresponding to the rear segment 232 of the top plate 23 receives a plurality of electronic components 40 of the computer system 10. The system fans 50 are arranged between the drawer 30 and the electronic components 40, and are distributed in a row that is perpendicular to the side plates 25. In this embodiment, the system fans 50 exhaust airflow from the drawer 30 to the exterior through the ventilating holes 270 of the end plate 27 of the casing 20.

The drawer 30 is made of metal, and is cuboid. A top side and a rear side of the drawer 30 are open. The drawer 30 includes a bottom surface 33, two sidewalls 32, and a front wall 31. The front wall 31 of the drawer 30 is rectangular, and substantially the same size as the opening of the casing 20. When the drawer 30 is entirely received in the casing 20, the front wall 31 of the drawer 30 seals the opening of the casing 20. A plurality of through holes 310 are defined in the front wall 31 of the drawer 30, corresponding to the ventilating holes 270 of the end plate 27 of the casing 20. In this embodiment, a sliding rail 35 is formed on each of the sidewalls 32 of the drawer 30, for facilitating sliding of the drawer 30. The sliding rails 35 can be omitted in alternative embodiments.

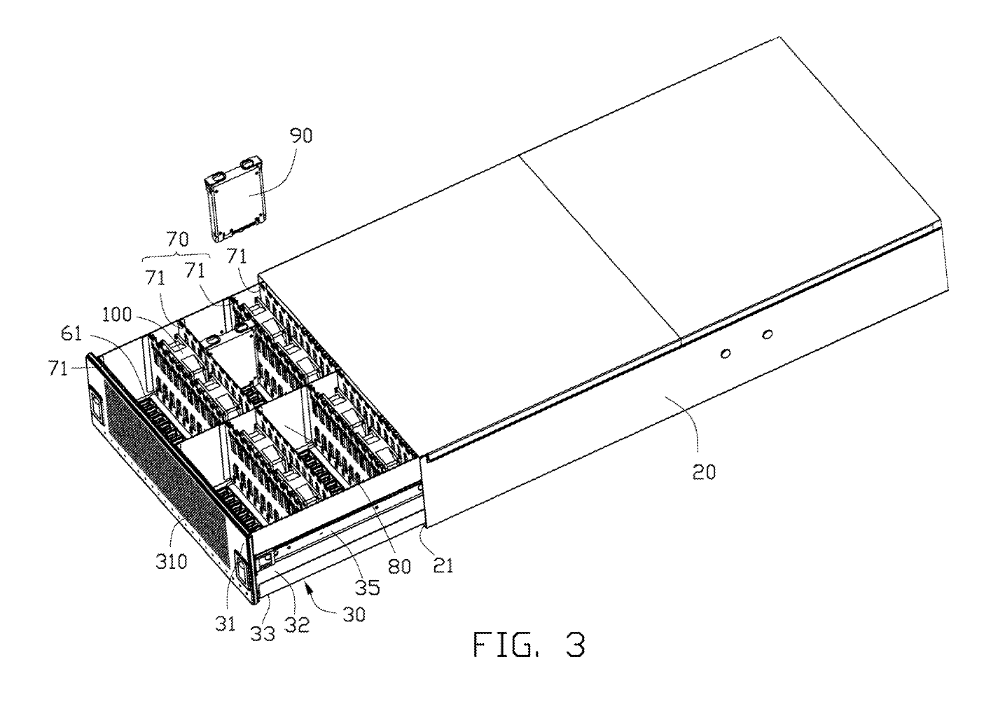

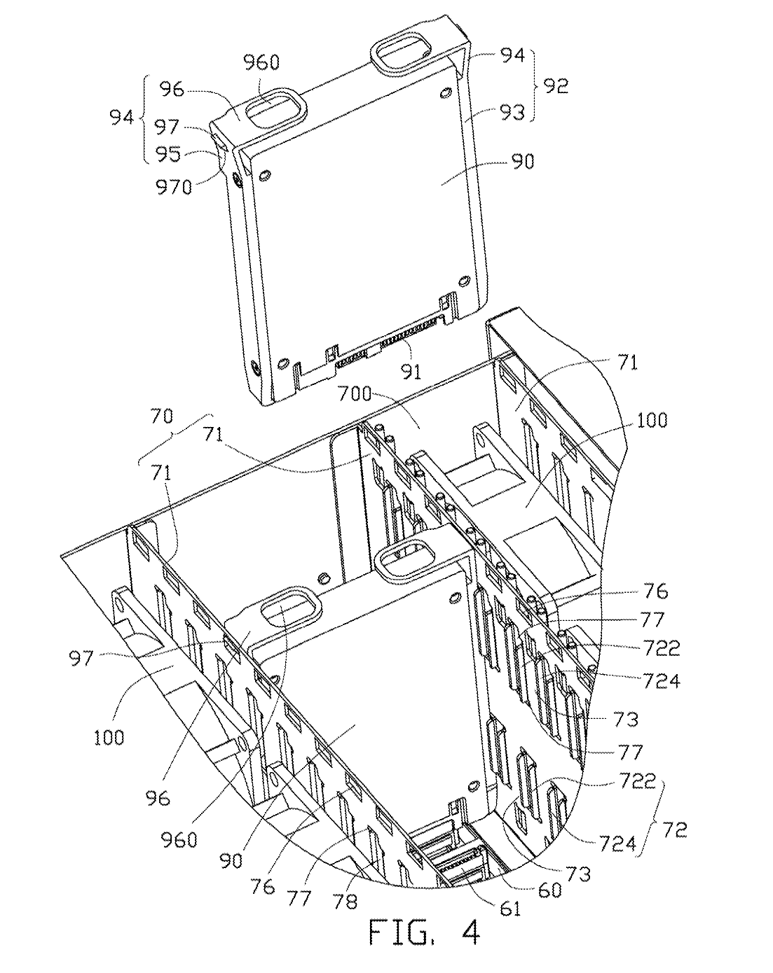

Referring to FIGS. 3 and 4, a circuit board 60 is disposed on the bottom surface 33 of the drawer 30. A plurality of sockets 61 on the circuit board 60 provides connection and positioning for the HDDs 90. A plurality of brackets 70 is provided on the circuit board 60. Each of the brackets 70 includes two parallel supporting boards 71, each of which is substantially a flat sheet. The brackets 70 are parallel to each other, and arranged one after another along a longitudinal axis of the casing 20. A chamber 700 is defined between each two neighboring brackets 70, and accommodates a plurality of cooling fans 100 therein. A connecting board 80 is arranged in the drawer 30, and perpendicularly intersects the brackets 70 to enhance the strength of the brackets 70. Alternatively, the connecting board 80 can be omitted if the unassisted strength of the brackets 70 is considered sufficient.

In this embodiment, three brackets 70 are deployed. A plurality of tabs 72 protrude outwards from each supporting board 71 towards the other supporting board 71 of the same bracket 70. In this embodiment, the tabs 72 of each supporting board 71 are arranged in two rows, one row above the other. The tabs 72 of each row are arranged in a series of pairs. The pairs of tabs 72 of each row are evenly spaced from each other along the longitudinal axis of the supporting board 71. The tabs 72 are integrally formed with the supporting board 71 by punching. An aperture 78 is defined in the supporting board 71 between each pair of tabs 72. The aperture 78 is rectangular, and elongated. A plurality of vent slots 77 is defined in each supporting board 71, corresponding to the apertures 78. Each aperture 78 has two corresponding vent slots 77. One of the two corresponding vent slots 77 is located over and communicates with the aperture 78, and the other corresponding vent slot 77 is located under and communicates with the aperture 78.

Each pair of tabs 72 includes a first tab 722 and a second tab 724, which are bent from the supporting board 71. The first tab 722 is adjacent to the lateral side of one aperture 78 at one side of the pair of tabs 72, and the second tab 724 is adjacent to the lateral side of another aperture 78 at the other opposite side of the pair of tabs 72. Preferably, the first tab 722 and the second tab 724 are parallel to each other, and are both perpendicular to the supporting board 71. A holding slot 73 is defined between the first tab 722 and the second tab 724 of each pair of tabs 72, for guiding and holding one end of a corresponding one of the HDDs 90 received in the drawer 30 of the casing 20. An intervening space (not labeled) is defined between each pair of directly opposite holding slots 73 of the two supporting boards 71 of each bracket 70. Such intervening space and the pair of holding slots 73 cooperatively define a receiving space (not labeled) for accommodating a corresponding HDD 90 therein. A plurality of latching holes 76 is defined in a top edge portion of the supporting board 71, with each latching hole 76 located above a respective holding slot 73.

Each HDD 90 has a connector 91 at a bottom end thereof, matching a corresponding one of the sockets 61 of the circuit board 60. Two latching members 92 are connected to opposite lateral thin sides of the HDD 90, respectively. Each latching member 92 includes a fixing arm 93 and a latching arm 94. The fixing arm 93 is fixed to the corresponding lateral side of the HDD 90 by fasteners (not labeled) such as screws. The latching arm 94 is generally L-shaped (or “7-shaped”), and includes an elastic piece 95, an operating piece 96 and a latching tab 97. The elastic piece 95 extends at an oblique angle outwards from a top end of the fixing arm 93. The latching tab 97 protrudes outwards from the elastic piece 95. An angled guiding face 970 is defined on an outer side of the latching tab 97. The operating piece 96 bends from a top end of the elastic piece 95 towards the other latching member 92. The operating pieces 96 are located over the top end of the HDD 90, parallel to the HDD 90. A notch 960 is defined in each of the operating pieces 96.

During installation of the HDDs 90, the drawer 30 is pulled out of the casing 20. Each HDD 90 is positioned over the drawer 30 and aligned with one corresponding receiving space. Then the HDD 90 is pressed downwardly along the holding slots 73 until the latching tabs 97 of the latching member 92 are snappingly received in the latching holes 76 of the bracket 70. In such position, the connector 91 at the bottom end of the HDD 90 electrically couples to the socket 61 of the circuit board 60. Since the elastic pieces 95 of the latching arms 94 are obliquely angled, when the elastic pieces 95 reach the top edges of the supporting boards 71 of the bracket 70 during installation of the HDD 90, the elastic pieces 95 deform toward each other to be generally vertical, thereby reducing the distance therebetween. After the latching tabs 97 are received in the latching holes 76, the elastic pieces 95 still remain slightly deformed, and apply counterforce to keep the latching tabs 97 securely engaged in the latching holes 76. Thus the HDDs 90 assembled in the drawer 30 are stably held in position. When all of the HDDs 90 are installed, the drawer 30 can be pushed back into the casing 20, and the computer system 10 can begin to operate.

When any of the HDDs 90 is to be detached from the drawer 30, first, the drawer 30 is pulled out of the casing 20. Then external force is applied by a user to the operating pieces 96 of the latching arms 94 of the HDD 90. This causes the elastic pieces 95 to deform toward each other, reducing the distance therebetween. Accordingly, the latching tabs 97 withdraw from the latching holes 76 when the distance between the elastic pieces 95 reaches a predetermined value. The HDD 90 can then be pulled up out of the receiving space by the operating pieces 96. Instead of the drawer 30 being pulled out of the casing 20, alternatively, the front segment 230 of the top plate 23 corresponding to the drawer 30 can be detached from the casing 20.

Referring to FIG. 5, during operation of the computer system 10, as heat is generated by the HDDs 90 and other electronic components 40, the system fans 50 and the cooling fans 100 draw ambient air into the casing 20 via the through holes 310 of the front wall 31 of the drawer 30. The air is forced to pass all over the HDDs 90 via the apertures 78 and the vent slots 77 of the supporting boards 71, and all over the electronic components 40 after that. The heated air flows out from the casing 20 via the ventilating holes 270 of the end plate 27, and dissipates the heat to the exterior ambient air at the rear of the casing 20. Since the cooling fans 100 and the system fans 50 are aligned in series along the airflow direction, airflows of the cooling fans 100 and the system fans 50 flow along the same direction, and thus disturbance of the airflows is avoided. Accordingly, the speeds and pressures of the airflows are kept at a high level, which enhances heat exchange between the airflows of the cooling fans 100 and the HDDs 90. Accordingly, the HDDs 90 can maintain a lower temperature.

It is to be understood, however, that even though numerous characteristics and advantages of certain embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

What is claimed is:

1. A computer system comprising:
a casing defining a plurality of ventilating holes therein;
a drawer slidably received in the casing, the drawer defining a plurality of through holes corresponding to the ventilating holes of the casing;
a circuit board received in the drawer, with a plurality of electrical sockets provided on the circuit board;
a plurality of spaced brackets arranged over the circuit board, each bracket comprising two parallel supporting boards, each supporting board defining a plurality of apertures therein;
a plurality of hard disk drives, each sandwiched between the two supporting boards of one of the brackets and coupled to one of the sockets, the hard disk drives and the apertures of each supporting board of the bracket being arranged in alternating fashion along a longitudinal direction of the bracket; and
a plurality of cooling fans disposed between the brackets for drawing air into the casing via the through holes of the drawer, the air flowing through the apertures to the ventilating holes to exit from the casing.

2. The computer system of claim 1, wherein each of the supporting boards of each bracket has a plurality of pairs of tabs extending therefrom, the tabs of each supporting board extending towards the tabs of the other supporting board of the same bracket, each pair of tabs defining a holding slot therebetween, the pair of tabs of one supporting board and a corresponding pair of tabs of the other supporting board engaging a corresponding one of the hard disk drives at the corresponding holding slots.

3. The computer system of claim 2, wherein each of the apertures of each supporting board is located between two corresponding adjacent pairs of tabs.

4. The computer system of claim 3, wherein each supporting board further defines a plurality of vent slots corresponding to the apertures, each aperture has two corresponding vent slots, one of the two corresponding vent slots is located over and communicates with the aperture, and the other corresponding vent slot is located under and communicates with the aperture.

5. The computer system of claim 1, wherein the plurality of through holes and the plurality of ventilating holes are arranged at opposite sides of the casing, respectively.

6. The computer system of claim 1, further comprising a connecting board intersecting and reinforcing the supporting boards of the brackets.

7. The computer system of claim 1, wherein at least one of the supporting boards of each bracket defines a plurality of latching holes, each latching hole is located generally between two corresponding neighboring apertures, a latching tab protrudes from at least one lateral side of each hard disk drive, and the latching tab of each hard disk drive engages in a corresponding latching hole of a corresponding supporting board to secure the hard disk drive in position in the corresponding bracket.

8. The computer system of claim 7, wherein each hard disk drive comprises at least one latching member fixed thereon, the latching member comprising a fixing arm fixed at the at least one lateral side of the hard disk drive, an elastic piece extending outwards at an oblique angle from a top end of the fixing arm, and an operating piece bending from a top end of the elastic piece, and the latching tab protruding outwards from the elastic piece.

9. The computer system of claim 8, wherein the operating piece is over the hard disk drive, and a notch is defined in the operating piece.

10. A computer system, comprising:
a casing defining a plurality of ventilating holes in one lateral side thereof;
a drawer received in the casing, the drawer comprising a front wall farthest from the one lateral side of the casing, a plurality of through holes defined in the front wall of the drawer, a rear side of the drawer nearest to the one lateral side of the casing and a top side of the drawer both being open;
a circuit board arranged at a bottom of the drawer;
a plurality of parallel brackets arranged on the circuit board, each bracket parallel to each of the front and rear sides of the drawer, a chamber defined between each two neighboring brackets, each bracket comprising two parallel supporting boards, each supporting board defining a plurality of apertures therein;
a plurality of hard disk drives disposed in the drawer, each of the hard disk drives being sandwiched between the two supporting boards of one of the brackets at a position between two neighboring apertures, and being coupled to the circuit board; and
a plurality of cooling fans disposed in the chambers for drawing air into the casing via the through holes of the drawer, the air flowing through the apertures to take away heat of the hard disk drives and finally exiting the casing via the ventilating holes.

11. The computer system of claim 10, wherein each supporting board of each bracket defines a plurality of latching holes, each latching hole is located generally between two corresponding neighboring apertures, a latching tab protrudes from each of two opposite lateral sides of each hard disk drive, and the latching tabs of each hard disk drive engage in corresponding latching holes of the two supporting boards of a corresponding bracket to secure the hard disk drive in position in the corresponding bracket.

12. The computer system of claim 10, wherein each of the supporting boards of each bracket has a plurality of pairs of tabs extending therefrom, the tabs of each supporting board extending towards the tabs of the other supporting board of the same bracket, each of the apertures of each supporting board is located between two corresponding adjacent pairs of tabs, each pair of tabs engaging one of the hard disk drives.

13. The computer system of claim 9, further comprising a plurality of system fans received in the casing, the system fans located between the rear side of the drawer and the one lateral side of the casing.

14. The computer system of claim 13, wherein the system fans and the cooling fans are aligned in series.

15. The computer system of claim 13, wherein the systems fans are adjacent to the rear side of the drawer, the computer system further comprising other electronic components located between the system fans and the one lateral side of the casing.

16. A computer system, comprising:
a casing defining a plurality of through holes and a plurality of ventilating holes at two opposite sides thereof, respectively;
a plurality of brackets distributed in the casing side by side along a direction perpendicular to each of the two opposite sides of the casing, each bracket comprising two parallel boards, each board defining a plurality of apertures;
a plurality of hard disk drives each sandwiched between the two parallel boards of a corresponding bracket, the hard disk drives and the apertures of each board of the bracket being arranged in alternating fashion along a longitudinal direction of the bracket;
a plurality of cooling fans disposed between the brackets; and
a plurality of system fans received in the casing and located between the plurality of brackets and the plurality of ventilating holes, the plurality of cooling fans and the plurality of system fans aligned with each other in series in a direction from the plurality of through holes to the plurality of ventilating holes.

17. The computer system of claim 16, wherein each board of each bracket has a plurality of pairs of tabs extending therefrom towards the tabs of the other board of the same bracket, each of the apertures of each supporting board is located between two corresponding adjacent pairs of tabs, each pair of tabs engaging one of the hard disk drives.

18. The computer system of claim 17, wherein each supporting board defines a plurality of vent slots corresponding to the apertures, each aperture has two corresponding vent slots, one of the two corresponding vent slots is located above the tabs and communicates with the aperture, and the other corresponding vent slot is located below the tabs and communicates with the aperture.

19. The computer system of claim 16, wherein each board of each bracket defines a plurality of latching holes therein, each latching hole is located generally between two corresponding neighboring apertures, a latching tab protrudes from each of two opposite lateral sides of each hard disk drive, and the latching tabs of each hard disk drive engages in corresponding latching holes of the two supporting boards of a corresponding bracket to secure the hard disk drive in position in the corresponding bracket.

20. The computer system of claim 16, further comprising a connecting board intersecting and reinforcing the boards of the brackets.
